(19) United States
(12) Patent Application Publication
(10) Pub. No.: US 2009/0087562 A1
(43) Pub. Date: Apr. 2, 2009

(54) METHOD OF PREPARING CROSS-LINKED ORGANIC GLASSES FOR AIR-GAP SACRIFICIAL LAYERS

(76) Inventors: Long Hua Lee, West Islip, NY (US); Karen K. Gleason, Lexington, MA (US)

Correspondence Address: GAUTHIER & CONNORS, LLP, 225 FRANKLIN STREET, SUITE 2300, BOSTON, MA, 02110, US

(21) Appl. No.: 12/234,896

(22) Filed: Sep. 22, 2008

Related U.S. Application Data
(60) Provisional application No. 60/975,601, filed on Sep. 27, 2007.

(51) Int. Cl. C23C 16/44

(52) U.S. Cl. 427/255.6; 427/255.28

(57) ABSTRACT

A method of forming a polymer film on a surface of a substrate is described. The method comprises placing a substrate on a substrate holder in a vapor deposition system, and introducing a process gas to the vapor deposition system, wherein the process gas comprises a monomer, a cross-linking monomer, and an initiator. Thereafter, the substrate is exposed to the process gas in order to form a polymer film on the substrate, wherein the polymer film thermally decomposes at a decomposition temperature.

### CROSS-REFERENCE TO RELATED APPLICATIONS

This application is related to and claims priority to U.S. Provisional Application No. 60/975,601, entitled “CROSSLINKED NEOPENTYL METHACRYLATE ORGANIC GLASSES FOR AIR-GAP SACRIFICIAL LAYERS”, filed on Sep. 27, 2007. The entire content of which is herein incorporated by reference in its entirety.

### BACKGROUND OF THE INVENTION

1. Field of the Invention

The invention relates to preparing a polymer on a substrate and, more particularly, to preparing a cross-linked organic glass for use in an air-gap structure on a substrate.

2. Description of Related Art

As is known to those in the semiconductor art, interconnect delay is a major limiting factor in the drive to improve the speed and performance of integrated circuits (IC). One way to minimize interconnect delay is to reduce inter-connect capacitance by using low dielectric constant (low-k) materials as the insulating dielectric for metal wires in the IC devices. Thus, in recent years, low-k materials have been developed to replace relatively high dielectric constant insulating materials, such as silicon dioxide. In particular, low-k films are being utilized for inter-level and intra-level dielectric layers between metal wires in semiconductor devices.

Additionally, in order to further reduce the dielectric constant of insulating materials, material films are formed with pores, i.e., porous low-k dielectric films. Such low-k films can be deposited by a spin-on dielectric (SOD) method similar to the application of photo-resist, or by chemical vapor deposition (CVD). Thus, the use of low-k materials is readily adaptable to existing semiconductor manufacturing processes. However, low-k films and, more specifically, porous low-k films have suffered integration problems including, but not limited to, poor thermal and mechanical performance, copper migration, damage during pattern etching, etc. As a result, for example, the integration of low-k films and porous low-k films has required the use of capping layers having a higher dielectric constant, as well as the development of techniques to restore the dielectric constant of these films resulting from carbon depletion at exposed surfaces, and other techniques to seal exposed pores in the surface of porous low-k films.

Furthermore, in yet another attempt to reduce the dielectric constant of insulating materials, air-gap structures are contemplated. According to one approach, air-gap structures are formed by depositing a sacrificial material on a substrate and then depositing a bridging material over the sacrificial material. Thereafter, at a later point in the device manufacturing process following metallization and planarization, the sacrificial material is decomposed and removed in order to leave a gap or void in its absence. Conventionally, the sacrificial material is removed using a chemical or thermal process. Thus, the sacrificial material plays the role of template or “void precursor”, wherein the void is formed upon decomposition of the sacrificial material by thermal treatment and diffusion of the decomposition products out of the multilayer assembly. Thermally degradable polymers have been a preferred choice for use as a sacrificial material.

However, despite the promise of superior electrical performance by this approach, thermally degradable materials still face formidable challenges including, but not limited to, solvent resistance, thermal stability, and mechanical strength. For example, numerous acids, bases and organic solvents are utilized in IC manufacturing, and the sacrificial materials must retain their original dimensions regardless of the presence of these chemicals. Dissolution of sacrificial materials or swelling should be rigorously controlled or excluded. Additionally, for example, chemical vapor deposition of barrier layers on sacrificial materials is anticipated to take place at a substrate temperature between about 250 degrees C. and about 320 degrees C. Hence, the sacrificial material must be thermally stable in this temperature range. Furthermore, for example, the mechanical properties of the sacrificial material, such as hardness and Young's modulus, should be sufficiently high to withstand chemical mechanical planarization (CMP) and flip chip bonding. Further yet, for example, the fraction of residue remaining on the substrate following thermal decomposition of the sacrificial material should be minimized to guarantee proper electrical performance.

### SUMMARY OF THE INVENTION

The invention relates to preparing a polymer, such as a cross-linked polymer, on a substrate. More particularly, the invention relates to preparing a cross-linked organic glass for use in an air gap structure on a substrate.

According to an embodiment, a method of forming a polymer film on a surface of a substrate is described. The method comprises placing a substrate on a substrate holder in a vapor deposition system, and introducing a process gas to the vapor deposition system, wherein the process gas comprising a monomer, a cross-linking monomer, and an initiator. Thereafter, the method comprises exposing the substrate to the process gas in order to form a polymer film on the substrate, wherein the polymer film thermally decomposes at a decomposition temperature. The monomer comprises one or more materials selected from the group consisting of trimethylsilylmethyl methacrylate (TMMA), propargyl methacrylate (PMA), cyclopentyl methacrylate (CPMA), neopentyl methacrylate (npMA), and poly (neopentyl methacrylate) (P(npMA)), and the cross-linking monomer comprises one or more materials selected from the group consisting of ethylene glycol diacrylate (EGDA), ethylene glycol dimethacrylate (EGDMA), 1,3-propanediol diacrylate (PDDA), and 1,3-propanediol dimethacrylate (PDDMA).

According to another embodiment, a method of forming a polymer film on a surface of a substrate is described. The method comprises placing a substrate on a substrate holder in a vapor deposition system, introducing a process gas to the vapor deposition system, wherein the introducing the process gas comprises introducing a monomer at a first flow rate, introducing a cross-linking monomer at a second flow rate, and introducing an initiator at a third flow rate, and exposing the substrate to the process gas in order to form a polymer film on the substrate, the polymer film thermally decomposes at a decomposition temperature. The method further comprises varying the first flow rate of the monomer relative to the second flow rate of the cross-linking monomer in order to adjust the decomposition temperature of the polymer film.

According to another embodiment, a sacrificial inter-metal dielectric for use in an air gap structure, comprising a P(npMA-co-EGDA) polymer film.

According to yet another embodiment, a method for forming an air gap structure is described, comprising: depositing a sacrificial layer on a substrate, the sacrificial layer comprising a polymer film selected from the group consisting of P(npMA-co-EGDA), P(npMA-co-EGDMA), P(CPMA-co-EGDA), and P(CPMA-co-EGDMA).

### BRIEF DESCRIPTION OF THE DRAWINGS

In the accompanying drawings:

FIGS. 1A through 1E illustrate a method of preparing an air gap structure;

FIG. 2 is a flow chart of a method of forming a polymer film on a substrate according to an embodiment;

FIG. 3 is a flow chart of a method of forming a polymer film on a substrate according to another embodiment;

FIG. 4 is a schematic cross-sectional view of a vapor deposition system according to an embodiment;

FIG. 5 provides Fourier transform infrared (FTIR) spectra for various material films;

FIG. 6 provides FTIR spectra for various material films; and

FIG. 7 provides FTIR spectra for various material films.

### DETAILED DESCRIPTION OF EXEMPLARY EMBODIMENTS

A method of preparing a cross-linked polymer on a substrate is disclosed in various embodiments. However, one skilled in the relevant art will recognize that the various embodiments may be practiced without one or more of the specific details, or with other replacement and/or additional methods, materials, or components. In other instances, well-known structures, materials, or operations are not shown or described in detail to avoid obscuring aspects of various embodiments of the invention. Similarly, for purposes of explanation, specific numbers, materials, and configurations are set forth in order to provide a thorough understanding of the invention. Nevertheless, the invention may be practiced without specific details. Furthermore, it is understood that the various embodiments shown in the figures are illustrative representations and are not necessarily drawn to scale.

Reference throughout this specification to “one embodiment” or “an embodiment” means that a particular feature, structure, material, or characteristic described in connection with the embodiment is included in at least one embodiment of the invention, but do not denote that they are present in every embodiment. Thus, the appearances of the phrases “in one embodiment” or “in an embodiment” in various places throughout this specification are not necessarily referring to the same embodiment of the invention. Furthermore, the particular features, structures, materials, or characteristics may be combined in any suitable manner in one or more embodiments. Various additional layers and/or structures may be included and/or described features may be omitted in other embodiments.

As described above, air gap structures are contemplated for further reducing interconnect capacitance and, in turn, reducing interconnect delay and improving the speed and performance of integrated circuits (IC). Therein, a capping layer or bridging material is formed over a sacrificial layer or sacrificial material, and the sacrificial layer or sacrificial material is decomposed and removed in order to leave a gap or void in its absence.

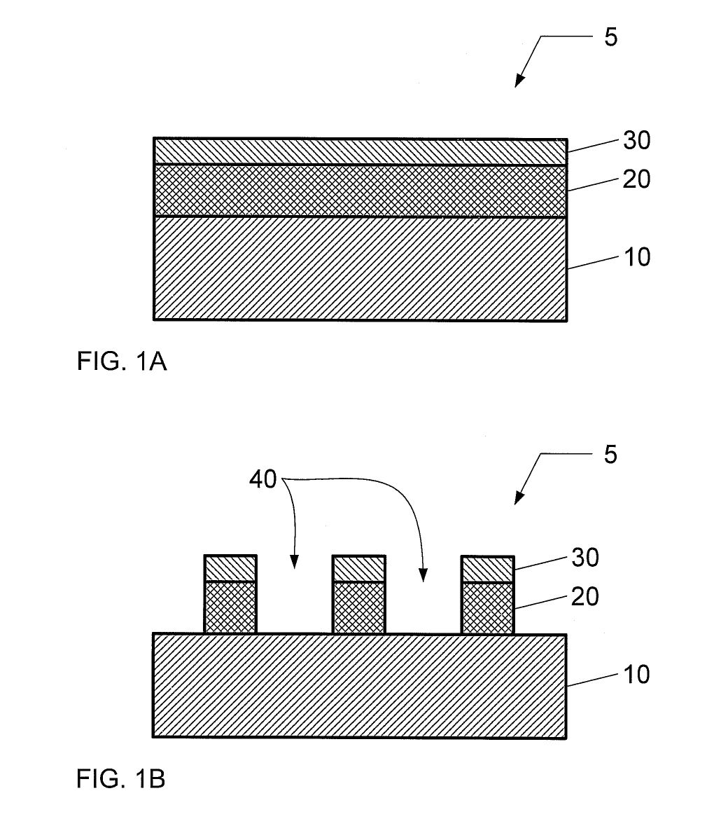

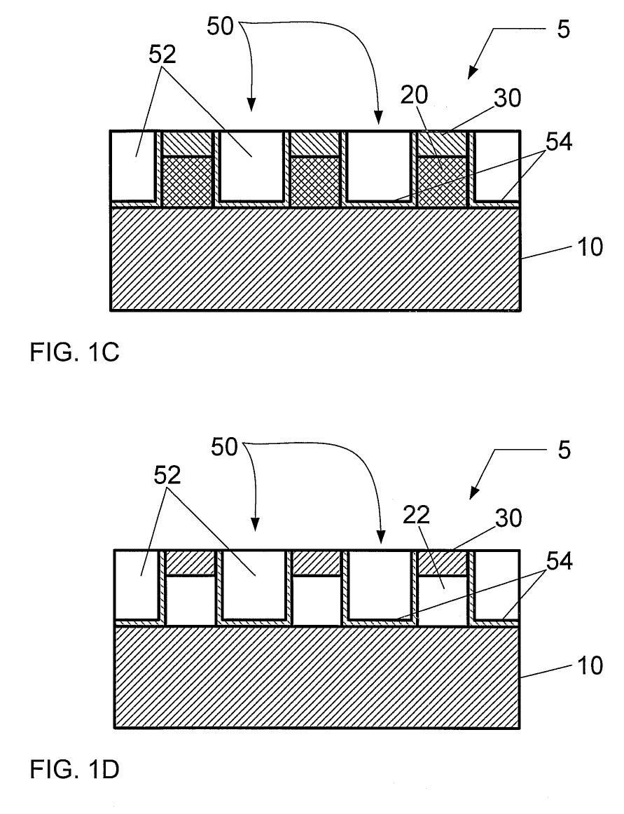

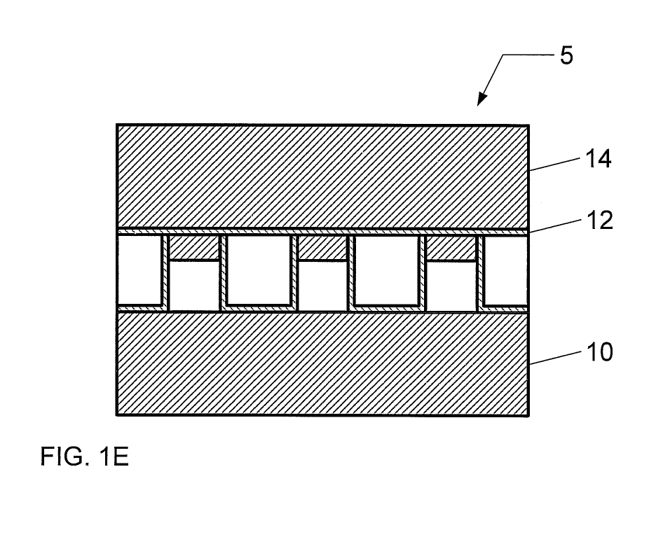

As an example, FIGS. 1A through 1E illustrate a procedure for preparing an air gap structure 5. As shown in FIG. 1A, the procedure comprises forming an inter-level dielectric (ILD) layer 10 on a substrate (not shown). Thereafter, a sacrificial inter-metal layer 20 is formed on the ILD layer 10, and a sacrificial cap layer 30 is formed on the sacrificial inter-metal layer 20. In FIG. 1B, a pattern 40 is transferred to the sacrificial inter-metal layer 20 and the sacrificial cap layer 30 using, for instance, a series of lithography and etching processes. The pattern 40 may correspond to the metal line pattern to be formed on the ILD layer 10.

In FIG. 1C, the pattern 40 is metalized to form a metal interconnect 50. The metal interconnect 50 may comprise metal lines 52, and a barrier layer 54 disposed between the metal lines 52 and the sacrificial inter-metal layer 20 and the sacrificial cap layer 30. For instance, the barrier layer 54 may reduce migration of the metal from metal lines 52 to the sacrificial inter-metal layer 20 and the sacrificial cap layer 30. The metallization of pattern 40 may comprise a series of deposition processes, and a planarization or polishing process.

In FIG. 1D, the sacrificial inter-metal layer 20 is decomposed and removed from air gap structure 5 to leave air gaps 22. Thereafter, as shown in FIG. 1E, a metal line cap layer 12 may be formed and a second ILD layer 14 may be formed on the metal line cap layer 12.

One candidate for the sacrificial inter-metal layer 20 is a polymer and, more particularly, a cross-linked polymer. Cross-linked polymers generally possess, among other things, higher chemical resistance, increased thermal stability, and superior mechanical properties when compared to their linear counterparts due to their rigid structure and the substantially lower mobility of polymer backbones.

Two strategies exist for synthesis of cross-linked polymers. One strategy involves simultaneous introduction of two monomers, wherein at least one monomer is multifunctional, followed by the copolymerization of the two monomer species. The other strategy involves polymerization of a single monomer with functional side groups, followed by reaction of the single monomer with externally supplied chemical species or exposure of the single monomer to an energy source so that cross-linking occurs. One requirement for use of the sacrificial inter-metal layer 20 in an air gap structure may include relatively clean decomposition of the sacrificial inter-metal layer 20, wherein only a minimal amount of residue remains on the substrate. Other requirements may include the onset temperature for polymer decomposition, monomer reactivity, and monomer volatility.

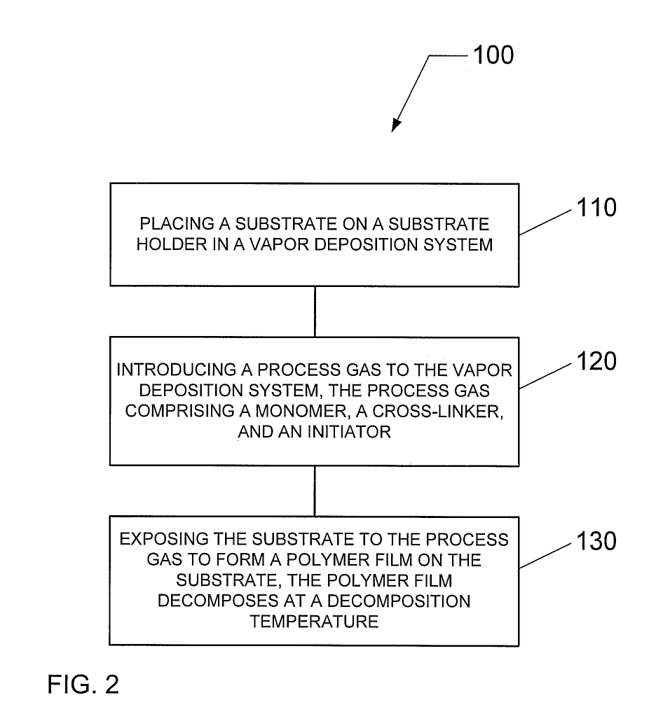

According to an embodiment, a method of forming a polymer film on a surface of a substrate is described. For example, the polymer film may be utilized in connection with an air gap structure as depicted in FIGS. 1A through 1E. As shown in FIG. 2, the method comprises a flow chart 100 beginning in 110 with placing a substrate on a substrate holder in a vapor deposition system. The substrate comprises a surface upon which the polymer film is deposited.

In 120, a process gas is introduced to the vapor deposition system, wherein the process gas comprises a monomer, a cross-linking monomer (or cross-linker), and an initiator. The process gas may include additional monomers, additional cross-linking monomers, or additional initiators, or any combination of two or more thereof. Thereafter, in 130, the method comprises exposing the substrate to the process gas in order to form the polymer film on the substrate, wherein the polymer film thermally decomposes at a decomposition temperature (onset temperature for degradation).

For example, the polymer film may comprise a copolymer film. Additionally, for example, the polymer film may comprise a methacrylate organic glass. Additionally, for example, the polymer film may comprise a cyclopentyl methacrylate organic glass or a neopentyl methacrylate organic glass. The polymer film may be formed using a vapor deposition process, such as a chemical vapor deposition (CVD) process, or an initiated CVD process (iCVD) as described in greater detail below. Other processes may include a pyrolytic CVD process or a hot-filament CVD (HFCVD) process.

The one or more monomers can comprise a methacrylate. Additionally, the one or more monomers can comprise a polymethacrylate. Furthermore, the one or more monomers may comprise trimethylsilylmethyl methacrylate (TMMA), propargyl methacrylate (PMA), cyclopentyl methacrylate (CPMA), neopentyl methacrylate (npMA), or poly (neopentyl methacrylate) (P(npMA)), or any combination of two or more thereof.

Additionally, the one or more cross-linking monomers can comprise a difunctional acrylate or a methacrylate. The one or more cross-linking monomers can comprise ethylene glycol diacrylate (EGDA), ethylene glycol dimethacrylate (EGDMA), 1,3-propanediol diacrylate (PDDA), or 1,3-propanediol dimethacrylate (PDDMA), or any combination of two or more thereof.

Furthermore, the one or more initiators can comprise a peroxide, an organic peroxide, a hydroperoxide, or a diazine, or any combination of two or more thereof. For example, the one or more initiators may comprise tert-butyl peroxide (TBPO).

The monomer, the cross-linking monomer, and the initiator may be heated in a vacuum system at moderate temperatures, and the vapors of the monomer, the cross-linking monomer, and the initiator are introduced to the vapor deposition system. The temperature for heating the monomer or the cross-linking monomer or both may be selected to avoid or reduce thermally-induced bulk polymerization. For example, the temperature for heating the monomer may be less than or equal to about 100 degrees C. Additionally, for example, the temperature for heating the cross-linking monomer may be less than or equal to about 100 degrees C. Additionally, the vapor deposition system may be temperature-controlled to avoid or reduce condensation of the vaporized monomer, or the vaporized cross-linking monomer, or both.

The vapors of the monomer, the cross-linking monomer, and the initiator may or may not be fully mixed prior to introduction to the vapor deposition system. For example, the vapors of the monomer, the cross-linking monomer, and the initiator may be partly mixed prior to introduction to the vapor deposition system. Alternatively, for example, the vapors of the monomer, the cross-linking monomer, and the initiator may be introduced to the vapor deposition system independent of one another without any prior mixing.

The method of forming the polymer film may further comprise introducing the monomer at a first flow rate, introducing the cross-linking monomer at a second flow rate, and introducing the initiator at a third flow rate. Additionally, the method may comprise setting a pressure in the vapor deposition system, and controlling the temperature of the substrate or substrate holder or both. For example, the temperature of the substrate may be controlled using the substrate holder. For example, the first flow rate may range from about 1 sccm (standard cubic centimeters per minute) to about 10 sccm, the second flow rate may range from about 0.1 sccm to about 1 sccm, the third flow rate may range from about 0.1 sccm to about 2 sccm, the pressure may range from about 1 mTorr (millitorr) to about 10 Torr, and the temperature of the substrate may range from about 20 degrees C. to about 100 degrees C. Additionally, for example, the first flow rate may range from about 1.35 sccm (standard cubic centimeters per minute) to about 5.2 sccm, the second flow rate may range from about 0.4 sccm to about 0.6 sccm, the third flow rate may range from about 0.45 sccm to about 1.3 sccm, the pressure may range from about 100 mTorr (millitorr) to about 3 Torr, and the temperature of the substrate may range from about 25 degrees C. to about 45 degrees C.

Furthermore, as described above, the method may comprise disposing a heating element in the vapor deposition system, wherein at least one of the monomer, the cross-linking monomer, or the initiator flow through, over, or by the heating element, and elevating the temperature of the heating element. For example, when the initiator flows through, over, or by the heating element, the initiator may dissociate into two or more free radicals. The initiator free radicals, the monomer, and the cross-linking monomer adsorb on the substrate where surface polymerization may take place.

The heating element may comprise a filament composed of a tungsten-containing material, a tantalum-containing material, a molybdenum-containing material, a rhenium-containing material, a rhodium-containing material, a platinum-containing material, or a nickel-containing material, or a combination thereof. For example, the temperature of the heating element may range from about 200 degrees C. to about 800 degrees C. Additionally, for example, the temperature of the heating element may range from about 245 degrees C. to about 355 degrees C.

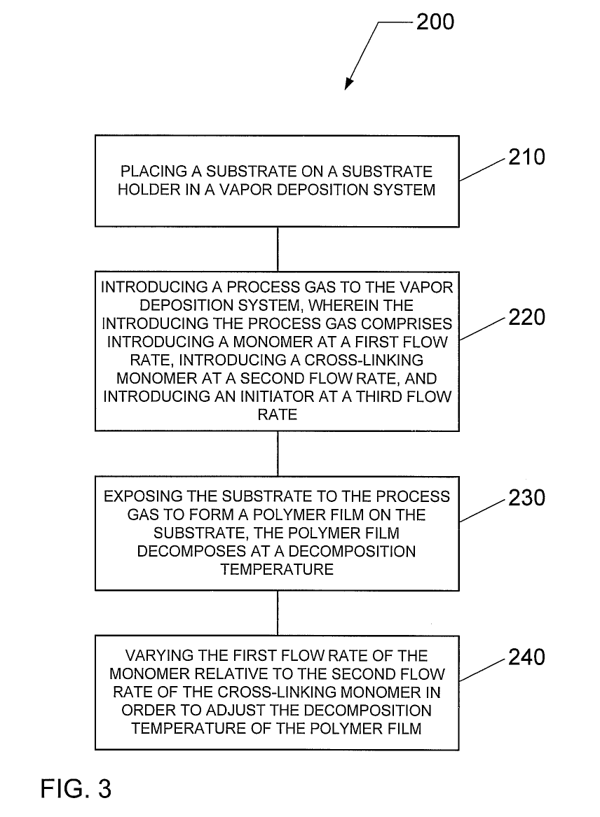

Referring now to FIG. 3, a method of forming a polymer film on a surface of a substrate is described according to another embodiment. For example, the polymer film may be utilized in connection with an air gap structure as depicted in FIGS. 1A through 1E. As shown in FIG. 3, the method comprises a flow chart 200 beginning in 210 with placing a substrate on a substrate holder in a vapor deposition system. The substrate comprises a surface upon which the polymer film is deposited.

In 220, a process gas is introduced to the vapor deposition system, wherein the introducing the process gas comprises introducing a monomer at a first flow rate, introducing a cross-linking monomer (or cross-linker) at a second flow rate, and introducing an initiator at a third flow rate. The process gas may include additional monomers, additional cross-linking monomers, or additional initiators, or any combination of two or more thereof. Thereafter, in 230, the method comprises exposing the substrate to the process gas in order to form the polymer film on the substrate, wherein the polymer film thermally decomposes at a decomposition temperature.

In 240, the first flow rate of the monomer is varied relative to the second flow rate of the cross-linking monomer in order to adjust the decomposition temperature of the polymer film. For example, by increasing the first flow rate relative to the second flow rate, the decomposition temperature may be decreased.

Following formation of the polymer film, the polymer film may be decomposed by elevating the temperature of the substrate at or above the decomposition temperature, and once decomposed the polymer film may be removed from the substrate. Furthermore, for example, by increasing the first flow rate relative to the second flow rate, the percentage of removal of the polymer film may be increased.

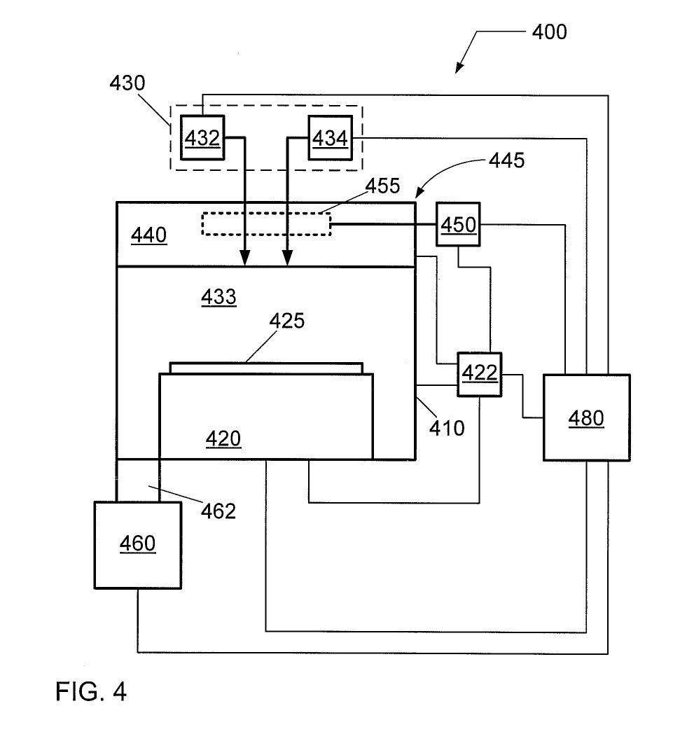

According to an embodiment, FIG. 4 schematically illustrates a vapor deposition system 400 for depositing a thin film, such as a polymer film. For example, the thin film may include a sacrificial inter-metal layer for use in air gap dielectrics. Vapor deposition system 400 can include a chemical vapor deposition (CVD) system, whereby a film forming composition is thermally activated or decomposed in order to form a film on a substrate. For example, the vapor deposition system 400 comprises a pyrolytic CVD system or initiated CVD system.

The vapor deposition system 400 comprises a process chamber 410 having a substrate holder 420 configured to support a substrate 425, upon which the thin film is formed. Furthermore, the substrate holder 420 is configured to control the temperature of the substrate 425 at a temperature suitable for the film forming reactions.

The process chamber 410 is coupled to a film forming composition delivery system 430 configured to introduce a process gas to the process chamber 410 through a gas distribution system 440. Furthermore, a gas heating device 445 is coupled to the gas distribution system 440 and configured to chemically modify the film forming composition. The gas heating device 445 comprises one or more heating elements 455 configured to interact with one or more constituents in the process gas, and a power source 450 that is coupled to the one or more heating elements 455 and is configured to deliver power to the one or more heating elements 455. For example, the one or more heating elements 455 can comprise one or more resistive heating elements. When electrical current flows through and affects heating of the one or more resistive heating elements, the interaction of these heated elements with one or more constituents in the process gas causes pyrolysis of one or more constituents of the process gas.

The process chamber 410 is further coupled to a vacuum pumping system 460 through a duct 462, wherein the vacuum pumping system 460 is configured to evacuate the process chamber 410 and the gas distribution system 440 to a pressure suitable for forming the thin film on the substrate 425 and suitable for pyrolysis of the process gas.

The film forming composition delivery system 430 can include one or more material sources configured to introduce the process gas to the gas distribution system 440. For example, the process gas may include one or more gases, or one or more vapors formed in one or more gases, or a mixture of two or more thereof. The film forming composition delivery system 430 can include one or more gas sources, or one or more vaporization sources, or a combination thereof. Herein vaporization refers to the transformation of a material (normally stored in a state other than a gaseous state) from a non-gaseous state to a gaseous state. Therefore, the terms “vaporization,” “sublimation” and “evaporation” are used interchangeably herein to refer to the general formation of a vapor (gas) from a solid or liquid precursor, regardless of whether the transformation is, for example, from solid to liquid to gas, solid to gas, or liquid to gas.

When the process gas is introduced to the gas distribution system 440, one or more constituents of the process gas are subjected to pyrolysis by the gas heating device 445 described above. The process gas can include film precursors that may or may not be fragmented by pyrolysis in the gas distribution system 440. The film precursor or precursors may include the principal atomic or molecular species of the film desired to be produced on the substrate. For example, the film precursor or precursors may include a monomer for the polymer film to be deposited. Additionally, the film forming composition can include a polymerizing agent (or cross-linker) that may or may not be fragmented by pyrolysis in the gas distribution system 440. The polymerizing agent may assist with the polymerization of a film precursor or fragmented film precursor on substrate 425. For example, the polymerizing agent may include a cross-linking monomer for the polymer film to be deposited.

Additionally yet, the process can include a reducing agent that may or may not be fragmented by pyrolysis in the gas distribution system 440. The reducing agent or agents may assist with the reduction of a film precursor on substrate 425. For instance, the reducing agent or agents may react with a part of or all of the film precursor on substrate 425.

Further yet, the process gas can include an initiator that may or may not be fragmented by pyrolysis in the gas distribution system 440. An initiator or fragmented initiator may assist with the fragmentation of a film precursor, or the polymerization of a film precursor. The use of an initiator can permit higher deposition rates at lower heat source temperatures. For instance, the one or more heating elements can be used to fragment the initiator to produce radical species of the initiator (i.e., a fragmented initiator) that are reactive with one or more of the remaining constituents in the process gas. Furthermore, for instance, the fragmented initiator or initiator radicals can catalyze the formation of radicals of the process gas.

As an example, when forming a polymer film, the process gas may comprise a monomer, a cross-linking monomer, and an initiator. The monomer, the cross-linking monomer, and the initiator may be selected from any one of the chemical species identified above.

According to one embodiment, the film forming composition delivery system 430 can include a first material source 432 configured to introduce one or more film precursors, such as a monomer and a cross-linking monomer, to the gas distribution system 440, and a second material source 434 configured to introduce a (chemical) initiator to the gas distribution system 440. Furthermore, the film forming composition delivery system 430 can include additional gas sources configured to introduce an inert gas, a carrier gas or a dilution gas. For example, the inert gas, carrier gas or dilution gas can include a noble gas, i.e., He, Ne, Ar, Kr, Xe, or Rn.

The one or more heating elements 455 can comprise one or more resistive heating elements. Additionally, for example, the one or more heating elements 455 may include a metal-containing ribbon or filament. Furthermore, for example, the one or more heating elements 455 can be composed of a resistive metal, a resistive metal alloy, a resistive metal nitride, or a combination of two or more thereof. The one or more heating elements 455 may comprise a filament or ribbon composed of a tungsten-containing material, a tantalum-containing material, a molybdenum-containing material, a rhenium-containing material, a rhodium-containing material, a platinum-containing material, or a nickel-containing material, or a combination thereof.

When the power source 450 couples electrical power to the one or more heating elements 455, the one or more heating elements 455 may be elevated to a temperature sufficient to pyrolize one or more constituents of the film forming composition. Power source 450 may include a direct current (DC) power source, or it may include an alternating current (AC) power source. Power source 450 may be configured to couple electrical power to the one or more heating elements 455 through a direct electrical connection to the one or more heating elements 455. Alternatively, power source 450 may be configured to couple electrical power to the one or more heating elements 455 through induction. Furthermore, for example, the power source 50 can be configured to modulate the amplitude of the power, or pulse the power. Furthermore, for example, the power source 50 can be configured to perform at least one of setting, monitoring, adjusting or controlling a power, a voltage, or a current.

Referring still to FIG. 4, a temperature control system 422 can be coupled to the gas distribution system 440, the gas heating device 445, the process chamber 410 and/or the substrate holder 420, and configured to control the temperature of one or more of these components. The temperature control system 422 can include a temperature measurement system configured to measure the temperature of the gas distribution system 440 at one or more locations, the temperature of the gas heating device 445 at one or more locations, the temperature of the process chamber 410 at one or more locations and/or the temperature of the substrate holder 420 at one or more locations. The measurements of temperature can be used to adjust or control the temperature at one or more locations in vapor deposition system 400.

The temperature measuring device, utilized by the temperature measurement system, can include an optical fiber thermometer, an optical pyrometer, a band-edge temperature measurement system as described in pending U.S. patent application Ser. No. 10/168,544, filed on Jul. 2, 2002, the contents of which are incorporated herein by reference in their entirety, or a thermocouple such as a K-type thermocouple. Examples of optical thermometers include: an optical fiber thermometer commercially available from Advanced Energies, Inc., Model No. OR2000F; an optical fiber thermometer commercially available from Luxtron Corporation, Model No. M600; or an optical fiber thermometer commercially available from Takaoka Electric Mfg., Model No. FT-1420.

Alternatively, when measuring the temperature of one or more resistive heating elements, the electrical characteristics of each resistive heating element can be measured. For example, two or more of the voltage, current or power coupled to the one or more resistive heating elements can be monitored in order to measure the resistance of each resistive heating element. The variations of the element resistance can arise due to variations in temperature of the element which affects the element resistivity.

According to program instructions from the temperature control system 422 or controller 480 or both, the power source 450 can be configured to operate the gas heating device 445, e.g., the one or more heating elements, at a temperature ranging from approximately 200 degrees C. to approximately 800 degrees C. For example, the temperature can range from approximately 245 degrees C. to approximately 335 degrees C. The temperature can be selected based upon the process gas and, more particularly, the temperature can be selected based upon a constituent of the process gas.

Additionally, according to program instructions from the temperature control system 422 or the controller 480 or both, the temperature of the gas distribution system 440 can be set to a value approximately equal to or less than the temperature of the gas heating device 445, i.e., the one or more heating elements. The temperature can be selected to be approximately equal to or less than the temperature of the one or more heating elements, and to be sufficiently high to prevent condensation which may or may not cause film formation on surfaces of the gas distribution system and reduce the accumulation of residue.

Additionally yet, according to program instructions from the temperature control system 422 or the controller 480 or both, the temperature of the process chamber 410 can be set to a value less than the temperature of the heat source 445, i.e., the one or more heating elements. The temperature can be selected to be less than the temperature of the one or more resistive film heating elements, and to be sufficiently high to prevent condensation which may or may not cause film formation on surfaces of the process chamber and reduce the accumulation of residue.

Once process gas enters the process space 433, constituents of the process gas adsorbs on the substrate surface, and film forming reactions proceed to produce a thin film on the substrate 425. According to program instructions from the temperature control system 422 or the controller 480 or both, the substrate holder 420 is configured to set the temperature of substrate 425 to a value less than the temperature of the gas heating device 445, the temperature of the gas distribution system 440, and the process chamber 410. For example, the substrate temperature can range up to approximately 80 degrees C. Additionally, the substrate temperature can be approximately room temperature. For example, the substrate temperature can range up to approximately 50 degrees C. Additionally, for example, the substrate temperature can range from about 20 degrees C. to about 100 degrees C. Additionally yet, for example, the substrate temperature can range from about 25 degrees C. to about 45 degrees C. However, the temperature may be less than or greater than room temperature.

The substrate holder 420 comprises one or more temperature control elements coupled to the temperature control system 422. The temperature control system 422 can include a substrate heating system, or a substrate cooling system, or both. For example, substrate holder 420 can include a substrate heating element or substrate cooling element (not shown) beneath the surface of the substrate holder 420. For instance, the heating system or cooling system can include a re-circulating fluid flow that receives heat from substrate holder 420 and transfers heat to a heat exchanger system (not shown) when cooling, or transfers heat from the heat exchanger system to the substrate holder 420 when heating. The cooling system or heating system may include heating/cooling elements, such as resistive heating elements, or thermo-electric heaters/coolers located within substrate holder 420. Additionally, the heating elements or cooling elements or both can be arranged in more than one separately controlled temperature zone. The substrate holder 420 may have two thermal zones, including an inner zone and an outer zone. The temperatures of the zones may be controlled by heating or cooling the substrate holder thermal zones separately.

Additionally, the substrate holder 420 comprises a substrate clamping system (e.g., electrical or mechanical clamping system) to clamp the substrate 425 to the upper surface of substrate holder 420. For example, substrate holder 420 may include an electrostatic chuck (ESC).

Furthermore, the substrate holder 420 can facilitate the delivery of heat transfer gas to the back-side of substrate 425 via a backside gas supply system to improve the gas-gap thermal conductance between substrate 425 and substrate holder 420. Such a system can be utilized when temperature control of the substrate is required at elevated or reduced temperatures. For example, the backside gas system can comprise a two-zone gas distribution system, wherein the backside gas (e.g., helium) pressure can be independently varied between the center and the edge of substrate 425.

Vacuum pumping system 460 can include a turbo-molecular vacuum pump (TMP) capable of a pumping speed up to approximately 5000 liters per second (and greater) and a gate valve for throttling the chamber pressure. For example, a 1000 to 3000 liter per second TMP can be employed. TMPs can be used for low pressure processing, typically less than approximately 1 Torr. For high pressure processing (i.e., greater than approximately 1 Torr), a mechanical booster pump and dry roughing pump can be used. Furthermore, a device for monitoring chamber pressure (not shown) can be coupled to the process chamber 410. The pressure measuring device can be, for example, a capacitance manometer.

Referring still to FIG. 4, the vapor deposition system 400 can further comprise controller 480 that comprises a microprocessor, memory, and a digital I/O port capable of generating control voltages sufficient to communicate and activate inputs to vapor deposition system 400 as well as monitor outputs from vapor deposition system 400. Moreover, controller 480 can be coupled to and can exchange information with the process chamber 410, the substrate holder 420, the temperature control system 422, the film forming composition supply system 430, the gas distribution system 440, the gas heating device 445, and the vacuum pumping system 460, as well as the backside gas delivery system (not shown), and/or the electrostatic clamping system (not shown). A program stored in the memory can be utilized to activate the inputs to the aforementioned components of vapor deposition system 400 according to a process recipe in order to perform the method of depositing a thin film.

Controller 480 may be locally located relative to the vapor deposition system 400, or it may be remotely located relative to the vapor deposition system 400 via an internet or intranet. Thus, controller 480 can exchange data with the vapor deposition system 400 using at least one of a direct connection, an intranet, or the internet. Controller 480 may be coupled to an intranet at a customer site (i.e., a device maker, etc.), or coupled to an intranet at a vendor site (i.e., an equipment manufacturer). Furthermore, another computer (i.e., controller, server, etc.) can access controller 480 to exchange data via at least one of a direct connection, an intranet, or the internet.

The vapor deposition system 400 can be periodically cleaned using an in-situ cleaning system (not shown) coupled to, for example, the process chamber 410 or the gas distribution system 440. Per a frequency determined by the operator, the in-situ cleaning system can perform routine cleanings of the vapor deposition system 400 in order to remove accumulated residue on internal surfaces of vapor deposition system 400. The in-situ cleaning system can, for example, comprise a radical generator configured to introduce chemical radical capable of chemically reacting and removing such residue. Additionally, for example, the in-situ cleaning system can, for example, include an ozone generator configured to introduce a partial pressure of ozone. For instance, the radical generator can include an upstream plasma source configured to generate oxygen or fluorine radical from oxygen (O₂), nitrogen trifluoride (NF₃), O₃, XeF₂, ClF₃, or C₃F₈ (or, more generally, CₓF_{y}), respectively. The radical generator can include an ASTRON® reactive gas generator, commercially available from MKS Instruments, Inc., ASTeX® Products (90 Industrial Way, Wilmington, Mass. 01887).

One example of a processing system that may be configured for an iCVD process is described in U.S. Pat. No. 6,887,578, entitled “Fluorocarbon-organosilicon copolymers and coatings prepared by hot-filament chemical vapor deposition” (Gleason et al.). Another example of a processing system that may be configured for an iCVD process is described in U.S. Patent Application Publication No. 2007/0032620 A1, entitled “Chemical vapor deposition of hydrogel films” (Gleason et al.).

According to an example, copolymerization of selected monomers and cross-linking monomers was performed to measure, among other things, deposition rate, onset temperature of degradation (T_{d}) (or decomposition temperature), and film removal percentage. Table 1 presents the deposition rate (nm/min, nanometers per minute), the onset temperature of degradation (T_{d}) (degrees C.), and the removal percentage (%) after heating the deposited film at 400 degrees C. for an hour under a nitrogen atmosphere for the four copolymers derived from permutations of monomers (npMA and CPMA) and cross-linking monomers (EGDMA and EGDA).

TABLE 1

| | Copolymer | |
|---|---|---|
| | P(npMA-co-EGDMA) | P(CPMA-co-EGDMA) |
| Deposition Rate | 61.5 | 63 |
| (nm/min) | | |
| T_{d} (degrees C.) | 230-240 | 240 |
| Removal Percent (%) | 99.58 +/− 0.01 | 99.57 +/− 0.26 |
| after 400 degrees C. | | |
| for 1 hour | | |
| | Copolymer | |
| | P(npMA-co-EGDA) | P(CPMA-co-EGDA) |
| Deposition Rate | 88.7 | 51.4 |
| (nm/min) | | |
| T_{d} (degrees C.) | 330 | 280-290 |
| Removal Percent (%) | 95.56 +/− 0.25 | 90.74 +/− 0.48 |
| after 400 degrees C. | | |
| for 1 hour | | |

P(npMA-co-EGDMA) and P(CPMA-co-EGDMA) decomposed cleanly (greater than 99% removal percentage); however, the onset temperatures for degradation were low compared to P(npMA-co-EGDA) and P(CPMA-co-EGDA). Increasing the amount of EGDMA in P(npMA-co-EGDMA) and P(CPMA-co-EGDMA) may improve the thermal stability, but the inventors suspect that an upper limit may exist at about 300 degrees C. (which is approximately the onset temperature for degradation of P(EGDMA)). On the other hand, despite of the fact that the copolymers P(npMA-co-EGDA) and P(CPMA-co-EGDA) did not decompose as cleanly as when EGDMA was used as the cross-linking monomer, the amount of residue may reduce with increasing the amount of the monomer. As for the monomer, npMA, as compared to CPMA, demonstrated an increased deposition rate, improved thermal stability, and increased removal percentage when cross-linked with EGDA.

As monomers, npMA and CPMA have approximately the same molecular weight (npMA: 156.22 Da, CPMA: 154.21 Da), dimension (npMA: 10.13 Å*5.20 Å* 5.30 Å; CPMA: 9.43 Å*5.93 Å*4.88 Å, as simulated by Gaussian Software), and vapor pressure (npMA: 0.923 torr; CPMA: 0.387 torr, calculated at 25 degrees C.). The major differences lie in the structures of the side groups, namely, neopentyl and cyclopentyl moieties. During polymerization, the presence of cyclopentyl groups in closer proximity to the radical center constitutes higher steric hindrance compared to that of neopentyl groups, and results in lower polymerization as well as deposition rates of homopolymer and copolymer. Indeed, at identical conditions, a lower deposition rate of P(CPMA) was observed (20 nm/min) compared to that of P(npMA) (30 nm/min). The availability of beta-hydrogen on cyclopentyl groups is unlikely to contribute to the lower removal percentage of P(CPMA-co-EGDA) since the beta hydrogens on alicyclic structure are much farther away (˜2.5 Å) from ester oxygen compared to linear aliphatic side groups (˜2.0 Å), such as in poly(n-pentyl methacrylate); the decomposition of P(CPMA) was also complete under the same thermal annealing conditions for P(npMA) which confirms that beta-hydrogen abstraction was not a major issue.

P(npMA-co-EGDA) may be used as a sacrificial inter-metal layer because the material comprises, among other things, suitable thermal stability, high deposition rate, and the potential of improving the removal percentage by increasing the methacrylate monomer content. Spectroscopic features, chemical/solvent resistance, thermal stability, degradation rates, and mechanical properties of the copolymer were investigated on copolymers having different compositions in order to understand the relation between the compositions and the properties and eventually optimize the performance.

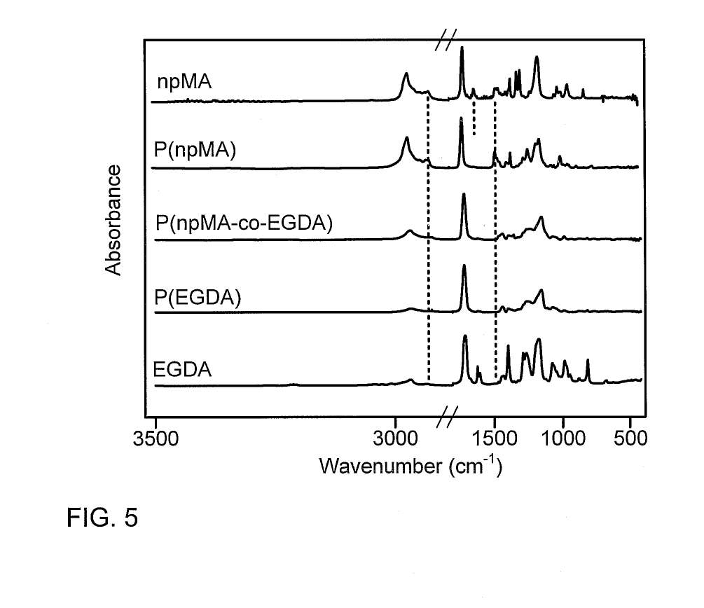

Referring now to FIG. 5, Fourier transform infrared (FTIR) spectra of npMA and EGDA monomers, their respective homopolymers P(npMA) and P(EGDA), as well as one of the copolymers P(npMA-co-EGDA) (Flow rate of npMA: 1.0 sccm). The peak of medium intensity at 1640 cm⁻¹ is characteristic of carbon-carbon double bonds for methacrylate monomers. The doublet peaks at 1635 cm⁻¹ and 1620 cm⁻¹ are characteristic of acrylic monomers due to symmetric and asymmetric stretching of carbon-carbon double bonds. Upon polymerization, these peaks disappear, indicating the complete consumption of vinyl bonds and confirming the feasibility of iCVD methodology. The FTIR spectrum of P(EGDA) shows a peak having marginally low intensity at the wavenumber characteristic of carbon-carbon double bond stretching, suggesting the presence of a small percentage of polymerizable groups in the polymer, as well as the homopolymers of other cross-linking monomers (FTIR not shown). This is quite common in polymerization of multi-functional monomers. Polymerizable groups not consumed at the initial stage of polymerization tend to survive as the reaction proceeds due to decreasing mobility of the polymer matrix.

The peak around 1730 cm⁻¹ is the stretching of carbonyl group. The carbonyl stretching modes at 1721 cm⁻¹ for npMA, 1728 cm⁻¹ for P(npMA) and EGDA, and 1735 cm⁻¹ for P(EGDA). The peak at 2870 cm⁻¹ is indicative of the methyl groups on neopentyl moieties of npMA and P(npMA), but is not observed for EGDA and its homopolymer, which both lack methyl groups. The peaks at 1480 cm⁻¹ and 1450 cm⁻¹ are C-H bending modes for npMA and EGDA, respectively, and these peaks do not show appreciable shift in the respective polymers. Both 1480 cm⁻¹ and 1450 cm⁻¹ were observed in the FTIR spectrum of P(npMA-co-EGDA) copolymer with attenuated intensities.

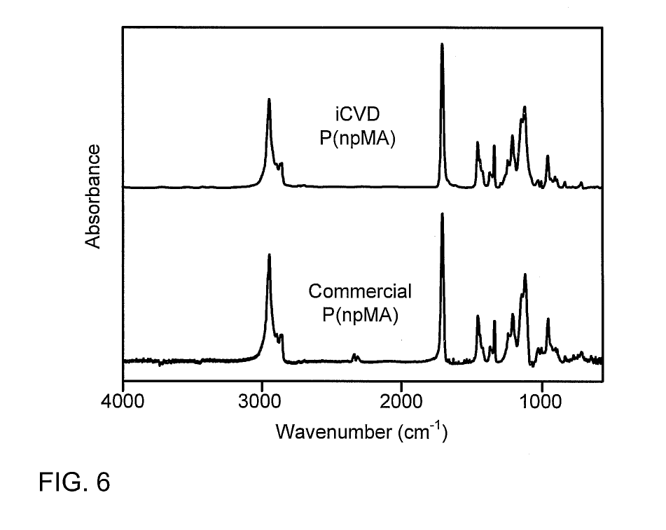

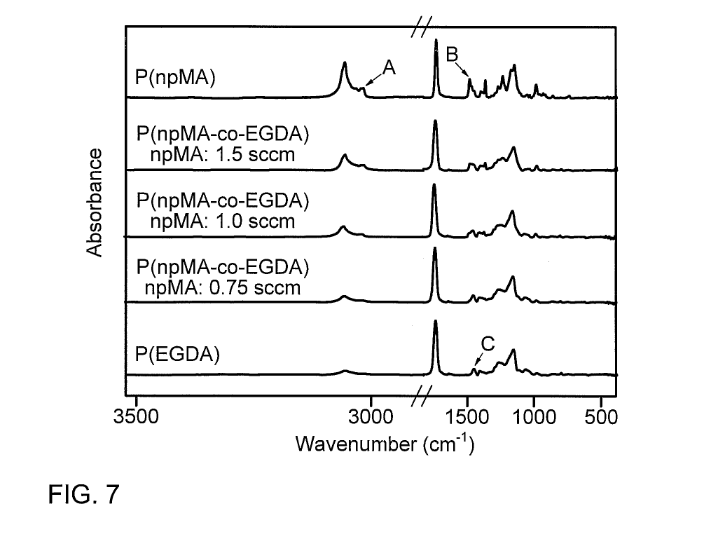

FIG. 6 shows the FTIR spectra of a commercial P(npMA) spun-cast film and the iCVD-synthesized P(npMA). The commercial sample was synthesized via a conventional free-radical polymerization pathway. The peak positions and relative intensities of the iCVD P(npMA) are essentially the same as the commercial intensities as shown in FIG. 6, and confirms that polymerization of npMA by iCVD methodology resulted in a similar product. FIG. 7 shows the systematic change in the intensities of these peaks in accordance with the increase in the flow rate of npMA. As the flow rate of npMA increased, the intensity of 1480 cm⁻¹ peak increased accordingly.

According to another example, the thicknesses of P(npMA-co-EGDA) copolymer thin films before and after interferometric thermal stability (ITS) experiments were measured by ellipsometry in the range of 315 to 700 nm. In ITS measurements, ITS response curves are acquired during thermal degradation of the polymer thin films. The ITS response curve includes interferometric laser signal data recorded as a function of temperature and time.

The original thickness of all samples was controlled at 1350±50 nm during the iCVD process. The removal percentage was calculated by dividing the difference in thicknesses before and after ITS experiments by the original thickness, and then multiplying by 100. Table 2 lists the onset temperature of degradation and the removal percentage for five copolymer films.

TABLE 2

| | Flow rate of npMA (sccm) | | | | |
|---|---|---|---|---|---|
| | 0.75 | 1 | 1.25 | 1.5 | 1.75 |
| Onset temperature of | 350 | 330 | 300 | 300 | 290 |
| degreadation | | | | | |
| (degrees C.) | | | | | |
| Removal Percentage | 93.59 +/− 0.23 | 95.56 +/− 0.25 | 97.12 +/− 0.06 | 97.17 +/− 0.01 | 97.88 +/− 1.06 |
| (%) | | | | | |
| | | | Substrate | Heating | |
| | | | holder | element | |
| Controlled Process | Flow rate of | Flow rate of | temperature | temperature | Pressure |
| Parameters | TBPO (sccm) | EGDA (sccm) | (degrees C.) | (degrees C.) | (mtorr) |
| 1.3 micron film | 0.5 | Constant | 30 | 280 | 760 |

In Table 2, a P(npMA-co-EGDA) film having a thickness of about 1.3 microns is deposited using an iCVD process, wherein the process gas comprises a monomer (npMA), a cross-linking monomer (EGDA), and an initiator (TBPO). The flow rate of npMA (sccm) is varied, while the remaining process parameters are controlled as follows: the flow rate of TBPO (initiator) is approximately 0.5 sccm; the flow rate of EGDA (cross-linking monomer) is held constant; the substrate holder temperature is approximately 30 degrees C.; the heating element temperature is approximately 280 degrees C.; and the pressure is approximately 760 mtorr. As shown in Table 2, a relative increase in the flow rate of npMA (monomer) correlates with a decrease in the onset temperature of degradation and an increase in the removal percentage.

Increasing the EGDA flow rate used for copolymer deposition was observed to enhance the thermal stability, but simultaneously reduce the removal percentage of the resultant films. The generation of secondary radicals, an intermediate if EGDA follows the monomer-unzipping mechanism, is energetically unfavorable compared to methacrylate monomers due to the reduced ability of delocalizing a radical center for acrylates (even though acrylates will eventually unzip under more rigorous conditions). However under these annealing conditions, other chemical bonds in polymers are also likely to rupture and therefore the thermal products of polyacrylates consist of fragments, monomers and oligomers. The extensive cross-links and the random arrangement of npMA and EGDA moieties also prevents the unzipping of the former in that segmental motion is severely retarded and the generation and propagation of radicals are suppressed. Therefore, the copolymer thin film became more thermally stable as the amount of EGDA increases.

TABLE 3

| Flow rate | Young's | Standard | | Standard |
|---|---|---|---|---|
| npMA | Modulus | Deviation of | | Deviation of |
| (sccm) | (Gpa) | Modulus (Gpa) | Hardness (Gpa) | Hardness (Gpa) |
| 0.75 | 4.93-5.37 | 0.122 | 0.67-0.73 | 0.019 |
| 1 | 4.79-5.28 | 0.108 | 0.53-0.57 | 0.014 |
| 1.25 | 4.38-4.88 | 0.18 | 0.48-0.53 | 0.016 |
| 1.5 | 4.35-4.81 | 0.186 | 0.44-0.51 | 0.019 |
| 1.75 | 3.97-4.60 | 0.186 | 0.39-0.47 | 0.036 |
| P(npMA) | 5.46-5.83 | 0.097 | 0.62-0.71 | 0.022 |
| P(EGDA) | 4.72-5.08 | 0.24 | 0.81-0.87 | 0.035 |

According to yet another example, nano-indentation experiments were conducted on a series of P(npMA-co-EGDA) copolymers and on homopolymers of P(npMA) and P(EGDA) to determine the values of the Young's modulus and the hardness. The modulus and hardness of P(npMA), P(EGDA), and P(npMA-co-EGDA) are listed in Table 3. The standard deviation for both mechanical properties are small compared to the measured values (<5%), implying the uniformity of the deposition.

As shown Table 3, the Young's moduli of the copolymers gradually decrease as the content of npMA in P(npMA-co-EGDA) increases, which is expected since the polymer matrices become less restricted and more mobile to external forces when the cross-linking densities decrease. Furthermore, as shown in Table 3, the values of hardness show the same trend (i.e., a gradual decrease in value with an increased content of npMA). For comparison, the Young's modulus and the hardness of PMMA obtained from a bulk mechanical test are 3.3 GPa and 0.195 GPa, respectively. The cross-linked copolymers are expected to be superior to linear PMMA in mechanical properties and indeed they are. However, the cross-linked copolymers exhibit mechanical properties that are marginally less than homopolymers of P(npMA) and P(EGDA).

Furthermore, P(npMA-co-EGDA) films may be deposited using iCVD, as described above, and may comprise a decomposable material having a thermal expansion coefficient less than or equal to 40 ppm/K. Further yet, P(npMA-co-EGDA) films may be deposited using iCVD, as described above, and may comprise a decomposable material having a dielectric constant less than or equal to 6.

Although only certain exemplary embodiments of this invention have been described in detail above, those skilled in the art will readily appreciate that many modifications are possible in the exemplary embodiments without materially departing from the novel teachings and advantages of this invention. Accordingly, all such modifications are intended to be included within the scope of this invention.

What is claimed is:

1. A method of forming a polymer film on a surface of a substrate, comprising:
placing a substrate on a substrate holder in a vapor deposition system;
introducing a process gas to said vapor deposition system, said process gas comprising a monomer, a cross-linking monomer, and an initiator; and
exposing said substrate to said process gas to form a polymer film on said substrate, said polymer film thermally decomposes at a decomposition temperature,
wherein said monomer comprises one or more materials selected from the group consisting of trimethylsilylmethyl methacrylate (TMMA), propargyl methacrylate (PMA), cyclopentyl methacrylate (CPMA), neopentyl methacrylate (npMA), and poly (neopentyl methacrylate) (P(npMA)), and said cross-linking monomer comprises one or more materials selected from the group consisting of ethylene glycol diacrylate (EGDA), ethylene glycol dimethacrylate (EGDMA), 1,3-propanediol diacrylate (PDDA), and 1,3-propanediol dimethacrylate (PDDMA).

2. The method of claim 1, wherein said polymer film comprises P(npMA-co-EGDA) (poly(neopentyl methacrylate-co-ethylene glycol diacrylate)), and said monomer comprises npMA (neopentyl methacrylate) and said cross-linking monomer comprises EGDA (ethylene glycol diacrylate).

3. The method of claim 2, wherein said P(npMA-co-EGDA) polymer film comprises a decomposable material having a thermal expansion coefficient less than or equal to 40 ppm/K.

4. The method of claim 2, wherein said P(npMA-co-EGDA) polymer film comprises a decomposable material having a dielectric constant less than or equal to 6.

5. The method of claim 2, wherein said P(npMA-co-EGDA) polymer film comprises a decomposable material having a hardness greater than or equal to about 0.4 GPa, and an elastic modulus greater than or equal to about 4 GPa.

6. The method of claim 2, further comprising:
controlling the temperature of said substrate using said substrate holder during said exposing.

7. The method of claim 1, wherein said initiator comprises a peroxide, a hydroperoxide, or a diazine, or any combination of two or more thereof.

8. The method of claim 1, wherein said initiator comprises tert-butyl peroxide (TBPO).

9. The method of claim 1, wherein said P(npMA-co-EGDA) polymer film is integrated as an inter-metal dielectric layer or part of an inter-metal dielectric layer to form an air gap structure.

10. The method of claim 1, further comprising:
introducing said monomer at a first flow rate;
introducing said cross-linking monomer at a second flow rate;
introducing said initiator at a third flow rate;
setting a pressure in said vapor deposition system;
controlling the temperature of said substrate;
disposing a heating element in said vapor deposition system, wherein at least one of said monomer, said cross-linking monomer, or said initiator flow through, over, or by said heating element; and
elevating the temperature of said heating element.

11. The method of claim 10, wherein said first flow rate ranges from about 1 sccm (standard cubic centimeters per minute) to about 10 sccm, said second flow rate ranges from about 0.1 sccm to about 1 sccm, said third flow rate ranges from about 0.1 sccm to about 2 sccm, said pressure ranges from about 1 mTorr (millitorr) to about 10 Torr, the temperature of said substrate ranges from about 20 degrees C. to about 100 degrees C., and the temperature of said heating element ranges from about 200 degrees C. to about 800 degrees C.

12. The method of claim 10, wherein said first flow rate ranges from about 1.35 sccm (standard cubic centimeters per minute) to about 5.2 sccm, said second flow rate ranges from about 0.4 sccm to about 0.6 sccm, said third flow rate ranges from about 0.45 sccm to about 1.3 sccm, said pressure ranges from about 100 mTorr (millitorr) to about 3 Torr, the temperature of said substrate ranges from about 25 degrees C. to about 45 degrees C., and the temperature of said heating element ranges from about 245 degrees C. to about 355 degrees C.

13. The method of claim 12, wherein said polymer film comprises P(npMA-co-EGDA), and wherein said monomer comprises npMA, said cross-linker comprises EGDA, and said initiator comprises TBPO.

14. The method of claim 10, wherein said disposing said heating element comprises disposing a filament composed of a tungsten-containing material, a tantalum-containing material, a molybdenum-containing material, a rhenium-containing material, a rhodium-containing material, a platinum-containing material, or a nickel-containing material, or a combination thereof.

15. The method of claim 10, further comprising:
varying said first flow rate of said monomer relative to said second flow rate of said cross-linker in order to adjust said decomposition temperature of said polymer film.

16. The method of claim 15, wherein said decomposition temperature of said polymer film decreases as said first flow rate increases relative to said second flow rate.

17. A method of forming a polymer film on a surface of a substrate, comprising:
placing a substrate on a substrate holder in a vapor deposition system;
introducing a process gas to said vapor deposition system, wherein said introducing said process gas comprises introducing a monomer at a first flow rate, introducing a cross-linking monomer at a second flow rate, and introducing an initiator at a third flow rate;
exposing said substrate to said process gas in order to form a polymer film on said substrate, said polymer film thermally decomposes at a decomposition temperature; and
varying said first flow rate of said monomer relative to said second flow rate of said cross-linker in order to adjust said decomposition temperature of said polymer film.

18. The method of claim 17, wherein said polymer film comprises P(npMA-co-EGDA), said monomer comprises npMA, said cross-lining monomer comprises EGDA, and said initiator comprises TBPO, and wherein said first flow rate ranges from about 0.75 sccm to about 1.75 sccm, said second flow rate is constant, and said decomposition temperature ranges from about 350 degrees C. to about 290 degrees C. during said increase in said first flow rate relative to said second flow rate.

19. The method of claim 17, further comprising:
decomposing said polymer film by elevating the temperature of said substrate at or above said decomposition temperature; and
removing said polymer film from said substrate,
wherein the percentage of removal of said polymer film increases as said first flow rate is increased relative to said second flow rate during the formation of said polymer film.

20. A sacrificial inter-metal dielectric for use in an air gap structure, comprising:
a P(npMA-co-EGDA) polymer film.

21. A method for forming an air gap structure, comprising:
depositing a sacrificial layer on a substrate, said sacrificial layer comprising a polymer film selected from the group consisting of P(npMA-co-EGDA), P(npMA-co-EGDMA), P(CPMA-co-EGDA), and P(CPMA-co-EGDMA).

22. The method of claim 21, wherein said depositing comprises performing an initiated CVD process.
